(19) United States
(12) Patent Application Publication
(10) Pub. No.: US 2008/0283860 A1
(43) Pub. Date: Nov. 20, 2008

(54) Light emitting device

(75) Inventors: Yoshinobu Suehiro, Aichi-ken (JP); Koji Tasumi, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 12/155,326

(22) Filed: Jun. 2, 2008

(30) Foreign Application Priority Data
Jun. 15, 2004 (JP) 2007-158523

(51) Int. Cl. H01L 33/00

(52) U.S. Cl. 257/98; 257/E33.001

(57) ABSTRACT

A light emitting device includes an emission portion, an optical control portion for reflecting or refracting light emitted from the emission portion in a predetermined direction, a light guiding member including a light input surface to which the reflected or refracted light is inputted, a refection region formed on a surface thereof for reflecting the inputted light, and a light output surface for externally outputting the reflected light from the refection region, a reflection portion, on which the emission portion is mounted and which covers externally the refection region, for dissipating heat generated from the emission portion and for reflecting light passing through the refection region in a direction of the light output surface, and a space formed between the light guiding member and the reflection portion.

The present application is based on Japanese patent application No. 2007-158523 filed on Jun. 15, 2007, the entire contents of which are incorporated herein by reference.

### BACKGROUND OF THE INVENTION

1. Field of the Invention

This invention relates to a light emitting device for radiating light in plane emission.

2. Description of the Related Art

JP-A-10-163527 discloses a plane emission light source that is composed of a light emitting element formed of GaN-based compound semiconductor and a phosphor layer for radiating white light, a light-guiding member for transmitting light emitted from the light emitting element and externally radiating light in plane emission, and a reflection portion disposed around the light guiding member for reflecting light emitted from the light emitting element, where the reflection portion is curved like a bow in cross section.

The plane emission light source of JP-A-10-163527 has the light emitting element with the phosphor layer built therein and, therefore, it is not necessary to provide a phosphor layer above or below the light guiding member so as to allow the total thickness of the plane emission light source to decrease.

JP-A-2003-173712 discloses a light emitting device that is composed of a light source, an opposite reflection mirror for reflecting light emitted from the light source in a desired direction, and a light guiding member with plural reflection surfaces for reflecting light introduced from the opposite reflection mirror, where the plural reflection surfaces are placed at a predetermined angle to the direction of light introduced from the opposite reflection mirror.

The light emitting device of JP-A-2003-173712 operates such that light emitted from the light source is reflected by the opposite reflection mirror in a predetermined direction, and the reflected light is further reflected by the plural reflection surfaces toward outside from the light emitting device. Thus, en elongated region can be irradiated by only the one light emitting element.

However, the plane emission light source of JP-A-10-163527 has a problem that, although it can be downsized and thinned by reducing the total thickness, it is difficult to efficiently dissipate heat generated from the light emitting element since its outer surface area is small.

The plane emission light source of JP-A-2003-173712 has a problem that, although light emitted from the light source can be externally radiated by using the plural refection surfaces, the remaining region of the light guiding member except the plural reflection surfaces cannot be used to externally radiate light, whereby light externally radiated from the light emitting device may cause an stripe emission pattern when the light source is low in brightness.

### SUMMARY OF THE INVENTION

It is an object of the invention to provide a light emitting device that heat dissipation property can be enhanced in dissipating heat from plural light emitting elements and light emitted from the plural light emitting elements can be efficiently extracted to outside of the device.

(1) According to one embodiment of the invention, a light emitting device comprises:

an emission portion;

an optical control portion for reflecting or refracting light emitted from the emission portion in a predetermined direction;

a light guiding member comprising a light input surface to which the reflected or refracted light is inputted, a refection region formed on a surface thereof for reflecting the inputted light, and a light output surface for externally outputting the reflected light from the refection region;

a reflection portion, on which the emission portion is mounted and which covers externally the refection region, for dissipating heat generated from the emission portion and for reflecting light passing through the refection region in a direction of the light output surface; and

a space formed between the light guiding member and the reflection portion.

In the above embodiment (1), the following modifications and changes can be made.

(i) The emission portion comprises a flip-chip mounted light emitting element.

(ii) The emission portion further comprises a glass material for sealing the light emitting element.

(iii) The light guiding member further comprises a parallel region formed on a surface thereof, adjacent to the refection region and parallel to the inputted light to the light input surface; and

the parallel region which allows light reflected by the reflection portion to pass therethrough.

(iv) The light guiding member further comprises a plurality of the refection regions and a plurality of the parallel regions; and

the plurality of the refection regions and the plurality of the parallel regions are arranged alternately and serially.

(v) The emission portion comprises a plurality of the light emitting elements disposed at predetermined intervals.

(vi) The plurality of the light emitting elements are disposed linearly.

(vii) The plurality of the light emitting elements are disposed in a matrix arrangement.

(viii) The glass material includes a phosphor for wavelength-converting light emitted from the light emitting element.

(ix) The light emitting device further comprises:

an insertion member between the emission portion and the reflection portion, the insertion member comprising a thermal expansion coefficient smaller than that of the reflection portion.

(x) The reflection portion comprises an annular mounting portion on which a plurality of the emission portions are mounted, and a throughhole inside the annular mounting portion.

(xi) The reflection portion further comprises a heat dissipation fin inside the throughhole.

(xii) The reflection portion comprises a mounting portion on which a plurality of the emission portions are mounted, and which comprises a thermal conductivity equal to or higher than the reflection portion.

(xiii) The light emitting device further comprises:

a cover member that covers externally the light output surface of the light guiding member, comprises an opening for extracting therethrough light outputted from the light output surface, and is connected to the reflection portion.

### BRIEF DESCRIPTION OF THE DRAWINGS

The preferred embodiments according to the invention will be explained below referring to the drawings, wherein:

FIG. 1A is a bottom view showing a light emitting device in a first preferred embodiment according to the invention;

FIG. 1B is a cross sectional view showing a part of the light emitting device of the first embodiment;

FIG. 2A is a top view showing a light source and an optical control portion of the first embodiment;

FIG. 2B is a cross sectional view showing the optical control portion of the first embodiment;

FIG. 2C is a cross sectional view showing a modification of the optical control portion of the first embodiment;

FIG. 3A is a cross sectional view showing an emission portion of the first embodiment;

FIG. 3B is a top view showing the emission portion of the first embodiment;

FIG. 4A is an enlarged cross sectional view showing a reflection region and a parallel region of a light guiding member of the first embodiment;

FIG. 4B is an enlarged cross sectional view showing a modification of the reflection region and the parallel region of the light guiding member of the first embodiment;

FIG. 5A is an enlarged cross sectional view showing a part of the light emitting device of the first embodiment;

FIG. 5B is an enlarged cross sectional view showing a part of the light emitting device of the first embodiment;

FIG. 6A is an enlarged cross sectional view showing a part of the emission portion and an insertion member of the first embodiment;

FIG. 6B is a cross sectional view showing the light emitting device of the first embodiment;

FIG. 7 is a cross sectional view showing a modification of the emission portion of the first embodiment;

FIG. 8 is a bottom view showing a modification of a refection portion of the first embodiment;

FIGS. 9A to 9C are cross sectional views showing a modification of the refection portion of the first embodiment;

FIG. 10A is a bottom view showing a light emitting device in a second preferred embodiment according to the invention;

FIG. 10B is a partial cross sectional view cut along a line B-B in FIG. 10A;

FIG. 11A is a top view showing an emission portion of the second embodiment;

FIG. 11B is a bottom view showing the emission portion of the second embodiment;

FIG. 12 is a cross sectional view showing an emission portion, an insertion member and a reflection portion of the second embodiment;

FIG. 13 is a bottom view showing a part of the light emitting device of the second embodiment;

FIG. 14A is a cross sectional view showing a part of a modification of the light emitting device of the second embodiment;

FIG. 14B is a bottom view showing the modification of the light emitting device of the second embodiment;

FIG. 15 is a cross sectional view showing a part of another modification of the light emitting device of the second embodiment; and

FIG. 16 is a cross sectional view showing a part of a further modification of the light emitting device of the second embodiment.

### DETAILED DESCRIPTION OF THE PREFERRED EMBODIMENTS

### First Embodiment

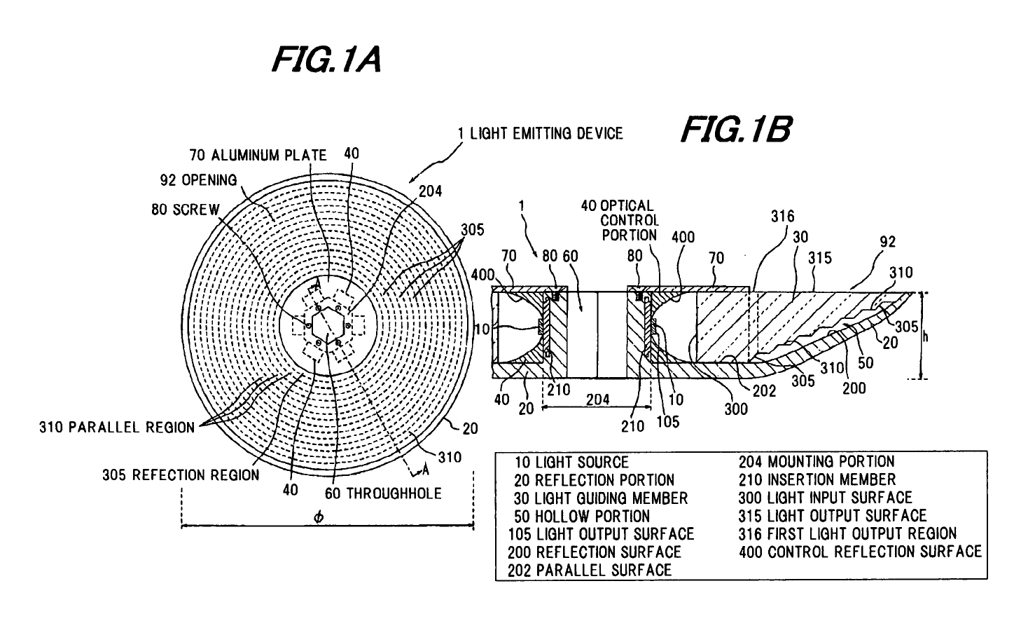

FIGS. 1A and 1B show a light emitting device in a first preferred embodiment according to the invention. FIG. 1A is a bottom view showing the light emitting device, and FIG. 1B is a cross sectional view showing a part of the light emitting device.

Construction of Light Emitting Device 1

The light emitting device 1 of this embodiment is constructed of a light source 10 with an emission portion 100, an optical control portion 40 with a control reflection surface 400 for reflecting or refracting light emitted from the light source 10 in a predetermined direction, an input surface 300 for inputting light emitted from the light source 10 or light reflected or refracted by the control reflection surface 400, and a light guiding member 30 including a refection region 305 formed at a predetermined angle with respect to light inputted through the input surface 300 and a parallel region 310 formed nearly parallel to light inputted through the input surface 300. Here, ‘nearly parallel’ means arranging parallel or subparallel and not needing to be accurately parallel.

The light emitting device 1 is further constructed of a reflection portion 20 with a reflection surface 200 for reflecting light passing through the refection region 305 and an annular mounting portion 204 for mounting the light source 10 through an insertion member 210 thereon, a hollow portion (i.e., a space or a gap) 50 formed between the light guiding member 30 and the reflection portion 20, and an aluminum plate 70 as a covering member for dissipating heat transferred from the light source 10 to the reflection portion 20. The aluminum plate 70 is fixed to the reflection portion 20 by screws 80.

The reflection portion 20 includes a parallel surface 202 which is formed connected with the reflection surface 200 and nearly parallel to a light output surface 315. A throughhole 60 is formed inside the mounting portion 204. The light guiding member 30 is provided with the light output surface 315 for outputting light reflected by the refection region 305 and light reflected by the reflection surface 200 and passing through the parallel region 310.

The reflection portion 20 mounts the emission portion 100 thereon and covers the refection region 305 on the outer side of the light guiding member 30. The reflection portion 20 is formed nearly circular in top view and has the throughhole 60 penetrating the front side to the back side of the reflection portion 20 in a predetermined range from the center of the circle. For example, the reflection portion 20 is 125 mm in outer diameter Φ and 10 mm in height. The throughhole 60 is formed nearly hexagonal in top view. The reflection portion 20 extends by a predetermined distance with a predetermined clearance spaced from the center, and has the parallel surface 202 nearly parallel to a light radiation plane of the light emitting device 1. Here, ‘nearly circular’ and ‘nearly hexagonal’ mean not needing to be accurately circular and hexagonal, respectively.

The reflection portion 20 is formed connected with the parallel surface 202, and has the reflection surface 200 curved at a predetermined curvature from the parallel surface 202 to an outer edge thereof. Here, the predetermined curvature is set to be such a value that, when light nearly parallel to the parallel surface 202 is inputted to the reflection surface 200, the light inputted to the reflection surface 200 can be reflected in a direction of the light radiation surface of the light emitting device 1.

The reflection portion 20 is provided with the throughhole 60 on the inner side and the annular mounting portion 204 for mounting the light source 10 with the plural emission portions 100. The mounting portion 204 has the light source 10 mounted via the insertion member 210 at a region where the light source 10 is mounted on the periphery of the throughhole 60. Thus, the insertion member 210 is inserted between the light source 10 with the emission portion 100 and the reflection portion 20.

In this embodiment, the insertion member 210 is disposed nearly perpendicular to the parallel surface 202 and has a predetermined thickness. For example, when the throughhole 60 is formed nearly hexagonal in top view, the plural insertion members 210 are disposed on sides of the hexagon.

The reflection portion 20 of this embodiment is about 100 W/(m·K) in thermal conductivity and formed of an aluminum alloy (die-casting alloy) with a thermal expansion coefficient of 21×10⁻⁶/° C. The reflection surface 200 is finished such that it can have a predetermined reflectivity to light emitted from the light source 10, e.g., mirror-finished. Meanwhile, in a separate process, an aluminum-composed layer with a predetermined thickness may be formed by deposition etc. on the surface of the reflection surface 200.

The insertion member 210 of this embodiment is formed of a material different from that of the reflection portion 20. The insertion member 210 may be formed of a material with a thermal expansion coefficient smaller than that of the material of the reflection portion 20. For example, the insertion member 210 is about 390 W/(m·K) in thermal conductivity and formed of an oxygen-free copper with a thermal expansion coefficient of 17×10⁻⁶/° C.

The optical control portion 40 is formed outside the annular mounting portion 204 and on the periphery of the throughhole 60. For example, the optical control portion 40 is formed in contact with the insertion member 210 and the reflection portion 20 at a region except a predetermined region where the light source 10 is mounted of the insertion member 210, at plural sides on the periphery of the throughhole 60. The optical control portion 40 is formed in parabolic shape (sectional view), and the light source 10 is placed in the predetermined region including the apex of the parabola. The optical control portion 40 has the control reflection surface 400 on the side where the light source 10 is placed.

The optical control portion 40 is formed of a transparent resin such as acrylic resin that is transparent to visible light. By forming a reflection material on the control reflection surface 400, light emitted from the light source 10 can be reflected thereon in a predetermined direction. In this case, the reflection material is formed a thin film on the surface of the control reflection surface 400.

The light source 10 is mounted through the insertion member 210 on the reflection portion 20. The light source 10 has plural emission portions for emitting white light. Light emitted from the emission portions of the light source 10 is externally discharged through a light output surface 105 of the light source 10. In this embodiment, the light emitting device 1 has the plural light sources 10. The plural light sources 10 are each mounted on the corresponding insertion members 210 placed on the periphery of the throughhole 60. The light sources 10 are each electrically connected to a wiring pattern formed on the insertion member 210 such that power is supplied through the wiring pattern.

The light guiding member 30 is shaped like a doughnut (top view). In other words, the light guiding member 30 is formed such that it surrounds the plural light sources 10 and the plural optical control portions 40. The light guiding member 30 is formed of a transparent resin that is transparent to light emitted from the light source 10. For example, the light guiding member 30 is formed of a transparent acrylic resin with a refractive index of about 1.49 to 1.50.

The light guiding member 30 of this embodiment is has on a side thereof a light input surface 300 to which light reflected or refracted in a predetermined propagation direction by the control reflection surface 400 and light emitted from the light source 10 are inputted. The light input surface 300 is arranged nearly parallel to the light output surface 105 of the light source 10. The light guiding member 30 has on another side thereof the plural refection regions 305 that are formed at a predetermined angle to light inputted to the light input surface 300 for reflecting it in the direction of the light output surface 315. For example, the predetermined angle of the refection region 305 with respect to light inputted to the light input surface 300 is 45 degrees. Between the light source 10 and the light input surface 300, there is provided a hollow portion, i.e., a space where the transparent resin or the like is not filled therein. The space is filled with gas (e.g., air) with a refractive index smaller than the light guiding member 30.

The light guiding member 30 extends in direction nearly perpendicular to the light input surface 300, extends to the outer edge of the reflection portion 20, and has the light output surface 315 for externally discharging light reflected by the refection region 305. The light guiding member 30 has on a side thereof the plural parallel regions 310 that are each adjacent to the plural refection regions 305 and arranged parallel to light inputted through the light input surface 300. For example, the refection region 305 and the parallel region 310 are alternately and serially arranged for light inputted through the light input surface 300 such that a stepwise shape is formed by the plural refection regions 305 and the plural parallel regions 310.

The hollow portion (i.e., a space or a gap) 50 is provided between the light guiding member 30 and the reflection portion 20. In this embodiment, the hollow portion 50 is defined by the air left between light guiding member 30 and the reflection portion 20. By the hollow portion 50, the reflection surface 200 inside the reflection portion 20 can be prevented from directly contacting the refection region 305 and the parallel region 310 of the light guiding member 30.

The aluminum plate 70 as a cover member is shaped like a doughnut (top view) and formed of an aluminum alloy. In this embodiment, the aluminum plate 70 covers a part of the light output surface 315 from outside the light guiding member 30 and defines an opening 92 for extracting light outputted from the light output surface 315.

For example, the aluminum plate 70 is arranged nearly parallel to the parallel surface 202 of the reflection portion 20. The aluminum plate 70 covers a predetermined region extending from the edge of the throughhole 60 to the outer edge of the reflection portion 20. For example, the aluminum plate 70 covers from the edge of the throughhole 60 to an inner end of a first light output region 316 of the light output surface 315 that allows the output of light reflected by the refection region 305 nearest to the throughhole 60. The aluminum plate 70 is fixed by the screws 80 to the reflection portion 20. Thus, the plural light sources 10 mounted via the insertion member 210 on the annular mounting portion 204 are located between the aluminum plate 70 and the parallel surface 202 of the reflection portion 20.

The reflection portion 20 may be shaped like a polygon (e.g., triangle, rectangular, hexagon, octagon etc.: top view) other than the circle (top view) as in this embodiment. Also, the throughhole 60 may be shaped like another polygon (e.g., triangle, rectangular, octagon etc.: top view) other than the hexagon (top view) as in this embodiment. The reflection portion 20 may be formed of another material with high thermal conductivity such as magnesium alloy (with thermal conductivity of about 70 W/(m·K)). With the reflection portion 20 of the magnesium alloy, the light emitting device 1 can be reduced in weight since the specific gravity of a magnesium alloy is about two thirds of an aluminum alloy.

The light source 10 may emit blue, red and/or green. A reflection material composing the control reflection surface 400 may be suitably selected according to wavelength of light emitted from the light source 10. The reflection material for exhibiting a predetermined reflectivity to wavelength of light emitted from the light source 10 may be formed on the control reflection surface 400. The predetermined reflectivity may be not less than 90% with respect to wavelength of light emitted from the light source 10.

Similarly, the reflection surface 200 of the reflection portion 20 may be processed to exhibit a predetermined reflectivity to wavelength of light emitted from the light source 10. For example, the reflection surface 200 can be mirror-finished to exhibit a predetermined reflectivity to wavelength of light emitted from the light source 10. Alternatively, a material for exhibiting a predetermined reflectivity to wavelength of light emitted from the light source 10 may be formed on the reflection surface 200.

The optical control portion 40 may be formed by using a prism. For example, above the light output surface 105 of the light source 10, the prism as the optical control portion 40 can be placed to guide light to the light input surface 300 of the light guiding member 30.

The angle of the plural refection regions 305 with respect to light inputted through the light input surface 300 is not limited to 45 degrees or uniformly 45 degrees. In other words, the angle of the plural refection regions 305 with respect to light inputted through the light input surface 300 may be different among the plural refection regions 305. For example, the angle of the plural refection regions 305 with respect to light inputted through the light input surface 300 may be individually set according to a desired radiation region for radiating light by the light emitting device 1.

The light guiding member 30 can be shaped by mechanically cutting the predetermined region of the transparent resin. Alternatively, the light guiding member 30 can be shaped by laser-cutting the predetermined region of the transparent resin. Furthermore, the light guiding member 30 can be shaped by filling acrylic resin in a predetermined mold and then curing it.

The aluminum plate 70 as a cover member may be on its outside shaped like a polygon (top view) other than the doughnut shape (top view) if only its inner shape is formed for providing a space corresponding to the throughhole 60. The aluminum plate 70 may be formed of a metallic material other than the aluminum alloy, e.g., magnesium alloy or oxygen-free copper.

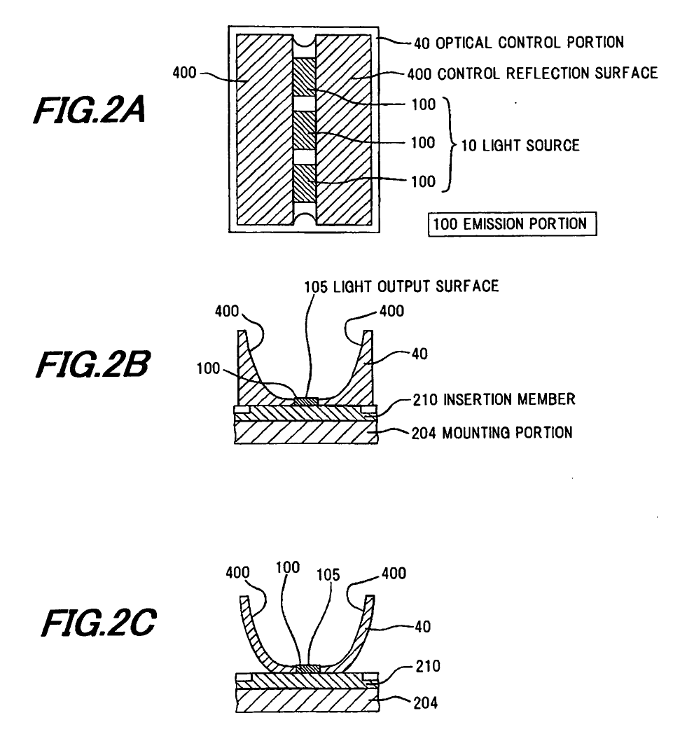

FIG. 2A is a top view showing the light source and the optical control portion of the first embodiment. FIG. 2B is a cross sectional view showing the optical control portion of the first embodiment. FIG. 2C is a cross sectional view showing a modification of the optical control portion of the first embodiment.

As shown in FIG. 2A, the optical control portion 40 is shaped like a rectangle (top view). On the other hand, as shown in FIG. 2B, the optical control portion 40 is curved like a parabola (cross sectional view). The plural emission portions 100 for emitting white light are disposed at predetermined intervals in a predetermined region including the apex of the parabola. The control reflection surface 400 is formed in a predetermined region of the top surface of the optical control portion 40, i.e., on the side where the light source 10 composed of the plural emission portions 100 is placed.

In this embodiment, the optical control portion 40 is formed of acrylic resin. The optical control portion 40 is provided with the control reflection surface 400 on the side where the emission portions 100 are placed. For example, the control reflection surface 400 is formed by depositing a metal such as aluminum on the top surface of the optical control portion 40.

As shown in FIG. 2C, a modification of this embodiment may be formed such that the optical control portion 40 is formed by bending a metal plate like a parabola. For example, the optical control portion 40 may be formed by bending the metal plate of oxygen-free copper with thermal conductivity higher than aluminum. In this case, the control reflection surface 400 can be formed by mirror finishing the surface of a copper plate or by depositing metal such as aluminum on the copper plate.

Although the light source 10 of this embodiment has the three emission portions 100, the number of the emission portions 100 included in the light source 10 may be one or two or more than three. In forming the control reflection surface 400 by depositing the metal on the surface of the optical control portion 40, the metal is not limited to aluminum. For example, the other metal such as Ag or a dielectric multilayer film can be suitably selected according to wavelength of light emitted from the emission portion 100 composing the light source 10. Especially, when light emitted from the emission portion 100 is not white light, the control reflection surface 400 may be formed by using a metal for exhibiting a reflectivity of not less than 90% with respect to wavelength of light emitted from the emission portion 100.

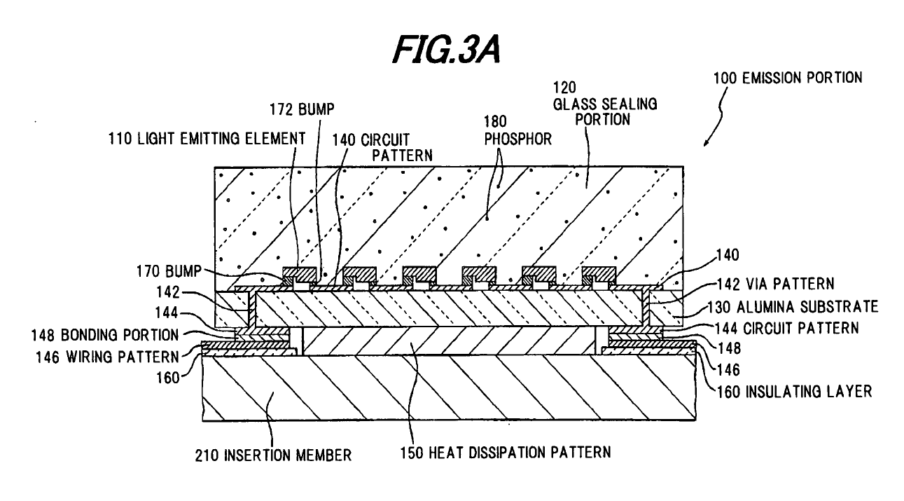

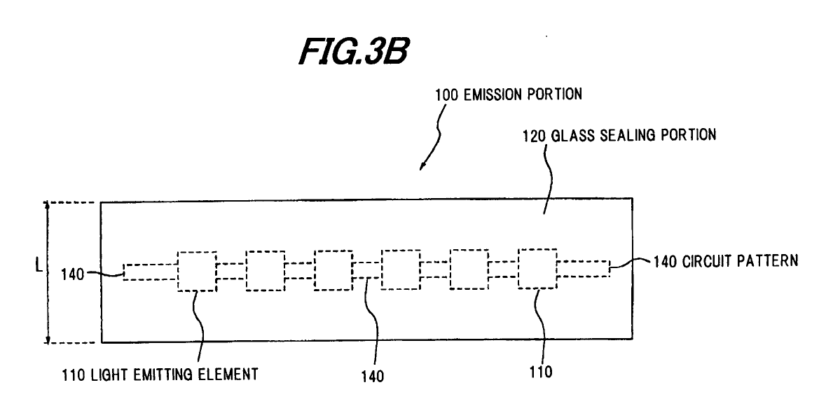

FIG. 3A is a cross sectional view showing the emission portion of the first embodiment. FIG. 3B is a top view showing the emission portion of the first embodiment.

As shown in FIG. 3A, the emission portion 100 is composed of an alumina substrate 130 as an insulating substrate, plural light emitting elements 110 for emitting blue light mounted on the alumina substrate 130, and a glass sealing portion 120 of a low-melting glass for sealing the plural light emitting elements 110. The plural light emitting elements 110 are mainly formed of a GaN-based compound semiconductor material.

The emission portion 100 is further composed of a circuit pattern 140 of a conductive material formed previously on the alumina substrate 130, plural bumps 170 and bumps 172 of a conductive material for electrically connecting each of the light emitting elements 110 to the circuit pattern 140, a phosphor 180 included in the glass sealing portion 120 for wavelength-converting light emitted from the light emitting element 110, plural via patterns 142 of a conductive material formed in a via hole provided in the alumina substrate 130, and plural circuit patterns 144 electrically connected through the via pattern 142 to the circuit pattern 140.

The circuit pattern 144 of the emission portion 100 is electrically connected through a bonding portion 148 to a wiring pattern 146 previously formed via an insulating layer 160 on the insertion member 210 of metal. The emission portion 100 is further composed of a heat dissipation pattern 150 that contacts both the emission portion 100 and the insertion member 210 when the emission portion 100 is mounted on the insertion member 210.

The alumina substrate 130 is formed of alumina (Al₂O₃) with thermal expansion coefficient of about 7×10⁻⁶/° C. The circuit pattern 140 of the conductive material is formed on the side of the alumina substrate 130 where the light emitting element 110 is mounted. For example, the conductive material may be a multiplayer metal film composed of tungsten (W)-nickel (Ni)-gold (Au) formed in this order on the alumina substrate 130. Alternatively, the circuit pattern 140 may be formed of a single conductive material such as Au, Cu or Al, or the other metallic material than the W—Ni—Au.

The circuit pattern 144 of the same conductive material as the circuit pattern 140 is formed on the side of the alumina substrate 130 opposite the side where the light emitting element 110 is mounted. The circuit pattern 140 is electrically connected to the circuit pattern 144 through the via pattern 142 formed in the via hole penetrating from the mounting surface of the light emitting element 110 on the alumina substrate 130 to the opposite surface thereon. The via pattern 142 is formed of the same conductive material as the circuit pattern 140.

The light emitting element 110 is composed of a sapphire substrate that has a thermal expansion coefficient of about 7×10⁻⁶/° C. in direction parallel to a c-axis thereof and (0001)-plane, an n-type GaN layer formed on the sapphire substrate, an InGaN layer as a light-emitting layer formed on the n-type GaN layer, a p-type GaN layer formed on the InGaN layer, and a p⁺-type GaN layer formed on the p-type GaN layer and having impurity concentration higher than the p-type GaN layer. The light emitting element 110 is further composed of a p-side electrode formed on the p⁺-type GaN layer, a bonding pad formed on the p-side electrode, and an n-side electrode formed on the n-GaN layer partially exposed by etching the p⁺-type GaN layer through the n-type GaN layer.

The n-type GaN layer, the InGaN layer, the p-type GaN layer and the p⁺-type GaN layer are each composed of a group III nitride compound semiconductor formed by MOCVD (metal organic chemical vapor deposition). For example, the n-type GaN layer is formed by doping Si as n-type dopant at a predetermined amount. The InGaN layer has a multiquantum well structure of InₓGa₁₋ₓN/GaN. The p-type GaN layer and the p⁺-type GaN layer are each formed by doping Mg as p-type dopant at a predetermined amount.

The light emitting element 110 thus composed is a light emitting diode (LED) for emitting light with a wavelength in a blue region. For example, it is a flip-chip type blue LED for emitting light with a peak wavelength of 460 nm in case of forward voltage=3.5 V and forward current=100 mA. The light emitting element 110 is shaped like a square (top view). The light emitting element 110 is about 0.35 mm square (top view) in size. The size of the light emitting element 110 is not limited to 0.35 mm square (top view) and may be changed in the range of 0.35 mm square (top view) to 3 mm square (top view). Alternatively, the light emitting element 110 may be formed like a rectangle such as 0.2 mm×0.4 mm (top view), where the plural light emitting elements 110 can be aligned along the longitudinal direction thereof so as to reduce the width needed in the arrangement thereof.

The plural light emitting elements 110 of this embodiment are placed adjacent to each other at predetermined intervals on the alumina substrate 130 and integrally sealed by a glass material. For example, as shown in FIG. 3B, the plural light emitting elements 110 are arranged along one direction at the predetermined intervals. In assembly, the plural light emitting elements 110 are placed such that they are aligned in direction perpendicular to the thickness direction of the light guiding member 30. Thereby, optical coupling efficiency to the light guiding member 30 can be enhanced such that high efficiency can be provided even by the low-profile light guiding member 30 that is easy to shape. The plural light emitting elements 110 are each electrically connected through the bumps 170, 172 to the circuit pattern 140 formed on the alumina substrate 130. Meanwhile, the light emitting elements 110 may not be arranged in a line. For example, in order to increase the amount of light, they may be arranged in plural lines such as two or three lines along the horizontal direction of the parallel surface 202. In this case, the light source 10 is formed like a rectangle. It is desirable that the light guiding member 30 has a width smaller than the other dimensions, so as to enhance the optical coupling efficiency of light emitted from the light source 10 with respect to the light input surface 300 of the light guiding member 30.

Instead of the emission portion 100 with the plural light emitting elements 110 mounted thereon, the plural emission portions 100 with one light emitting element 110 may be arranged in a line in direction perpendicular to the thickness direction of the light guiding member 30. In this case, freedom in changing the interval between the emission portions 100 can be increased although, in case of the emission portion 100 with the plural light emitting elements 110 mounted thereon, the workability can be enhanced by facilitating the mounting of the emission portion 100.

The n-side electrode of the light emitting element 110 is electrically connected through the bump 170 to the circuit pattern 140. The p-side electrode of the light emitting element 110 is electrically connected through the bump 172 to the circuit pattern 140. The bumps 170, 172 are mainly formed of a metallic material such as Au.

The glass sealing portion 120 is formed of transparent and colorless low-melting point glass that can be hot-pressed at about 600° C., and has the same thermal expansion coefficient (about 7×10⁻⁶/° C.) as the light emitting element 110 and the alumina substrate 130. Thus, the glass sealing portion 120 is formed of the glass material that has the same thermal expansion coefficient as the alumina substrate 130 composing the emission portion 100. In this embodiment, the glass sealing portion 120 is formed of ZnO—SiO₂—R₂O-based glass material (where R is at least one element selected from alkali metal elements). The glass sealing portion 120 is formed like a rectangle (top view). For example, the glass sealing portion 120 is 0.85 mm in width L. Where the glass sealing portion 120 is formed like a rectangle (top view), it can be formed different in dimensions of width, length and thickness.

The glass sealing portion 120 includes the phosphor 180 dispersed therein. The phosphor 180 of this embodiment may be a yellow phosphor that radiates yellow light with a peak wavelength in a yellow region by being excited by blue light emitted from the light emitting element 110. For example, a YAG phosphor can be used that does not change in property due to heat generated when glass-sealing the plural light emitting elements 110. Thus, the emission portion 100 can radiate white light.

The insertion member 210 of this embodiment is provided with the insulating layer 160 formed thereon and the wiring pattern 146 formed on the insulating layer 160. The wiring pattern 146 is electrically connected through the bonding portion 148 to the plural circuit patterns 144. The bonding portion 148 is formed of a metallic material such as AuSn solder. The insulating layer 160 is formed except the region on the insertion member 210 where the heat dissipation pattern 150 is placed, and formed of an insulating material such as SiO₂, SiON. The wiring pattern 146 is formed of the same conductive material as the circuit pattern 140.

The heat dissipation pattern 150 is formed of oxygen-free copper with a thermal conductivity of about 390 W/(m·K). The heat dissipation pattern 150 is formed on the side of the alumina substrate 130 opposite the side where the light emitting element 110 is mounted. For example, the heat dissipation pattern 150 is formed like a rectangle (top view). The heat dissipation pattern 150 has a thickness, e.g., about 10 μm such that there is no clearance between the surface of alumina substrate 130 opposite the side where the light emitting element 110 is mounted and the insertion member 210.

In this embodiment, the light emitting element 110 is an LED for emitting light with a wavelength in a blue region. However, in another embodiment or example of the invention, it may be an LED for emitting light with a wavelength in a ultraviolet, violet or green region. The layer structure of group III nitride compound semiconductor composing the light emitting element 110 is not limited to the above-mentioned layer structure if only it can emit light with a predetermined wavelength. In another embodiment or example of the invention, the light emitting element 110 may be an LED composed of another compound semiconductor such as ZnO-based, ZnSe-based, GaAs-based, GaP-based or InP-based compound semiconductor. When the light emitting element 110 can emit blue, green or red light as monochromatic light, the glass sealing portion 120 may not include the phosphor 180.

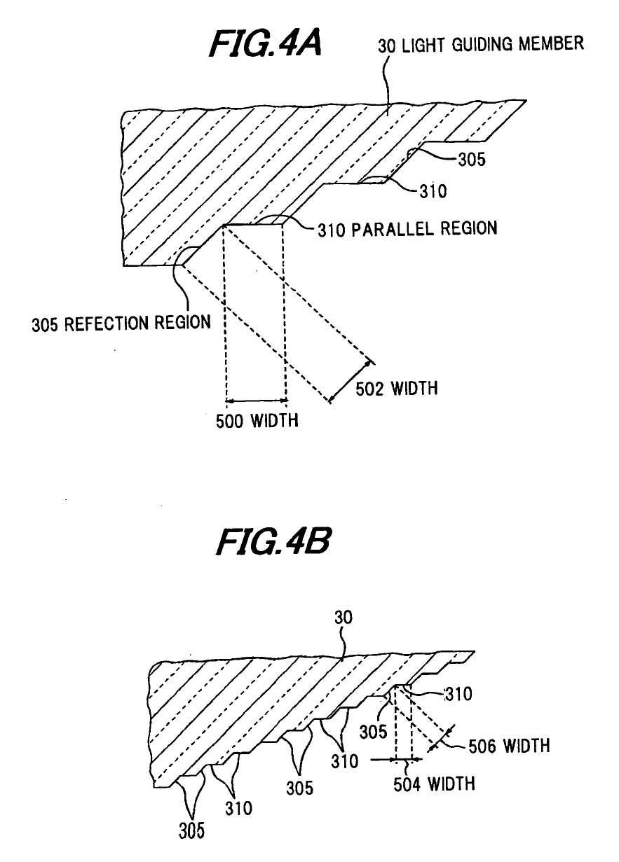

FIG. 4A is an enlarged cross sectional view showing the reflection region and the parallel region of the light guiding member of the first embodiment. FIG. 4B is an enlarged cross sectional view showing a modification of the reflection region and the parallel region of the light guiding member of the first embodiment.

As shown in FIG. 4A, the refection region 305 and the parallel region 310 are, adjacent to each other, alternately and serially arranged for light inputted through the light input surface 300. In other words, the plural refection regions 305 and the plural parallel regions 310 are, adjacent to each other, alternately and serially arranged for light inputted through the light input surface 300 such that a stepwise shape (cross sectional view) is formed thereby. In this embodiment, an angle defined between the surface of the refection region 305 and the surface of the parallel region 310 is about 45 degrees. In this embodiment, the parallel region 310 is about 10 mm in width 500 and the refection region 305 is about 0.9 mm in width 502.

As shown in FIG. 4B, in the modified embodiment, width 504 of the parallel region 310 and width 506 of the refection region 305 may be smaller than the widths 500 and 502, respectively, of this embodiment. For example, the width 500 may be about 1.0 mm and the width 502 may be about 0.09 mm. Furthermore, the width of the refection region 305 may be smaller or greater than that of the parallel region 310.

Operation of the Light Emitting Device 1

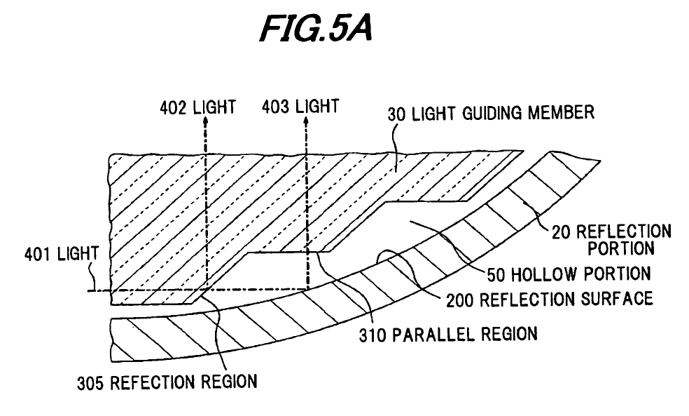

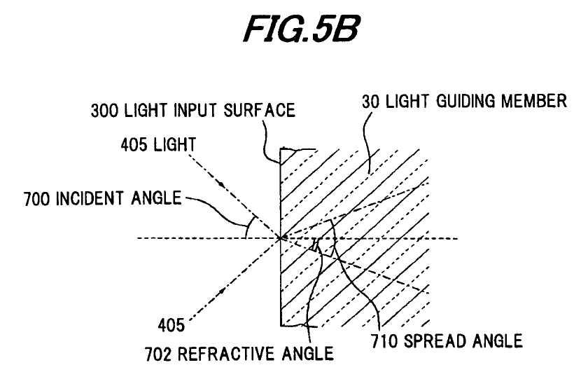

FIG. 5A is an enlarged cross sectional view showing a part of the light emitting device of the first embodiment.

Of light emitted from the light source 10 with the plural emission portions 100, a light component parallel to the normal line of the light input surface 300 of the light guiding member 30 is inputted directly to the light input surface 300. On the other, of light emitted from the light source 10, a light component in direction of the control reflection surface 400 of the optical control portion 40 is reflected or refracted by the control reflection surface 400 such that it is indirectly inputted to the light input surface 300.

As shown in FIG. 5A, light 401 inputted to the light input surface 300 passes through the light guiding member 30 along the normal line of the light input surface 300. The light 401 reaching the refection region 305 is reflected by the refection region 305 in direction of the light output surface 315 (See light 402). This is because the refection region 305 formed at a predetermined to light inputted through the light input surface 300 functions as a reflection mirror for light inputted through the light input surface 300 due to the difference in refractive index between the light guiding member 30 and the hollow portion 50.

The light guiding member 30 of this embodiment is formed of transparent acrylic resin and has a refractive index of about 1.49 to 1.50. In contrast, the hollow portion 50 is formed of the air which is about 1.0 in refractive index.

Here, a part of light the light 401 passes through the refection region 305 and is then reflected by the reflection surface 200 of the reflection portion 20 in direction of the parallel region 310, i.e., the light output surface 315 just above. For example, a part of light reflected by the reflection surface 200 passes through the parallel region 310 in direction of the light output surface 315 (See light 403). Thus, light from the light source 10 is externally discharged through the light output surface 315 of the light guiding member 30 by being reflected by the refection region 305 or being reflected by the reflection surface 200 and passing through the parallel region 310.

FIG. 5B is an enlarged cross sectional view showing a part of the light emitting device of the first embodiment.

As shown in FIG. 5B, light 405 inputted at incident angle 700 to the light input surface 300 is refracted by a refractive angle 702 in the light guiding member 30. In this embodiment, a space is formed of the air where light 405 emitted from the light source 10 passes through before reaching the light input surface 300. On the other, the light guiding member 30 is formed of acrylic resin. Therefore, the refractive angle 702 is smaller than the incident angle 700. As a result, light 405 inputted at the incident angle 700 to the light input surface 300 is collected within a spread angle 710 defined by largeness of the refractive angle 702 in the light guiding member 30.

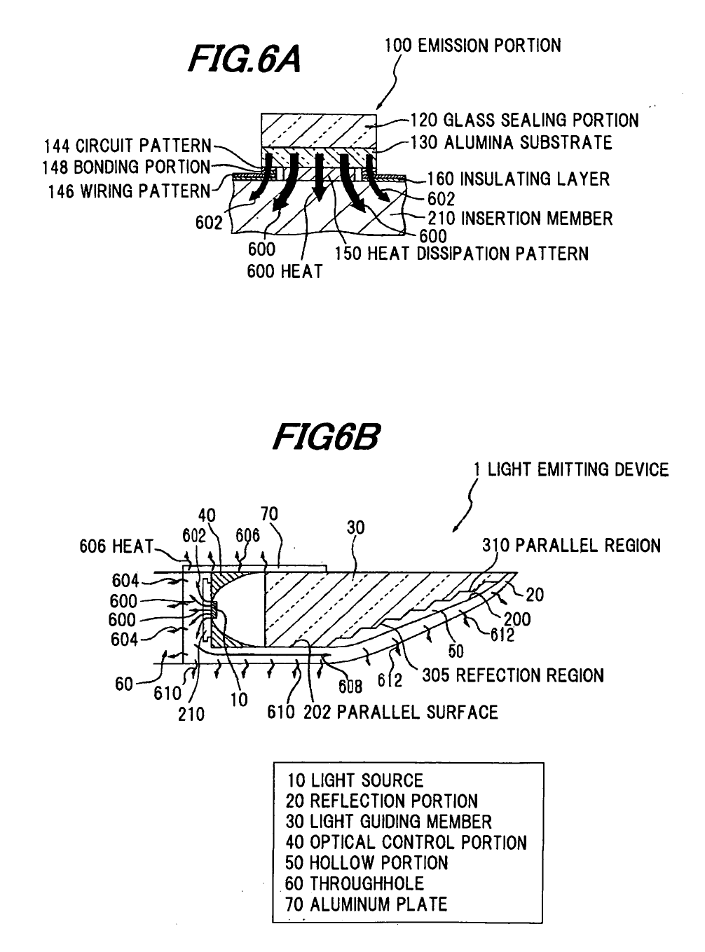

FIG. 6A is an enlarged cross sectional view showing a part of the emission portion and the insertion member of the first embodiment. FIG. 6B is a cross sectional view showing the light emitting device of the first embodiment.

As shown in FIG. 6A, heat 600 generated from the plural light emitting elements of the emission portion 100 by supplying power thereto is transferred through the heat dissipation pattern 150 contacting the alumina substrate 130 to the insertion member 210. Also, a part (heat 602) of heat generated from the plural light emitting elements is transferred to the insertion member 210 through the circuit pattern 144 on the alumina substrate 130, the bonding portion 148 contacting the circuit pattern 144, the wiring pattern 146 contacting the bonding portion 148 and the insulating layer 160 contacting the wiring pattern 146.

In this embodiment, since the heat dissipation pattern 150 is formed of oxygen-free copper with thermal conductivity lower than the alumina substrate 130, heat generated from the plural light emitting elements 110 of the emission portion 100 is transferred preferentially through the heat dissipation pattern 150 to the insertion member 210. Then, heat 600 and heat 602 from the heat dissipation pattern 150 is transferred through the insertion member 210 to the reflection portion 20. Here, the insertion member 210 has a thermal expansion coefficient smaller than the reflection portion 20. Therefore, the insertion member 210 is less in thermal expansion/contraction caused by heat from the emission portion 100 than the case that the emission portion 100 is directly mounted on the reflection portion 20 where heat from the emission portion 100 is directly transferred to the reflection portion 20.

As shown in FIG. 6B, heat 600 transferred from the emission portion 100 to the insertion member 210 is dissipated from parts of the reflection portion 20. For example, heat 604 as a part of heat 600 is transferred in direction of the throughhole 60 of the reflection portion 20 and externally dissipated from the surface of the throughhole 60. On the other, heat 606 as a part of heat 600 is transferred in direction of the aluminum plate 70 and externally dissipated from the surface of the aluminum plate 70.

Further, heat 608 as a part of heat 600 is transferred in direction of the parallel surface 202 and the reflection surface 200 of the reflection portion 20. Then, heat 608 is externally dissipated from the surface of the parallel surface 202 opposite the side where the parallel surface 202 contacts the optical control portion 40 and the light guiding member 30 (See heat 610). A part of heat 608 transferred to the reflection surface 200 is externally dissipated from the surface of the reflection surface 200 opposite the side where the reflection surface 200 contacts the hollow portion 50 (See heat 612). Thus, the hollow portion 50 placed between the reflection surface 200 and the light guiding member 30 functions as a heat insulator that prevents heat transfer from the reflection surface 200 to the refection region 305 and the parallel region 310 of the light guiding member 30.

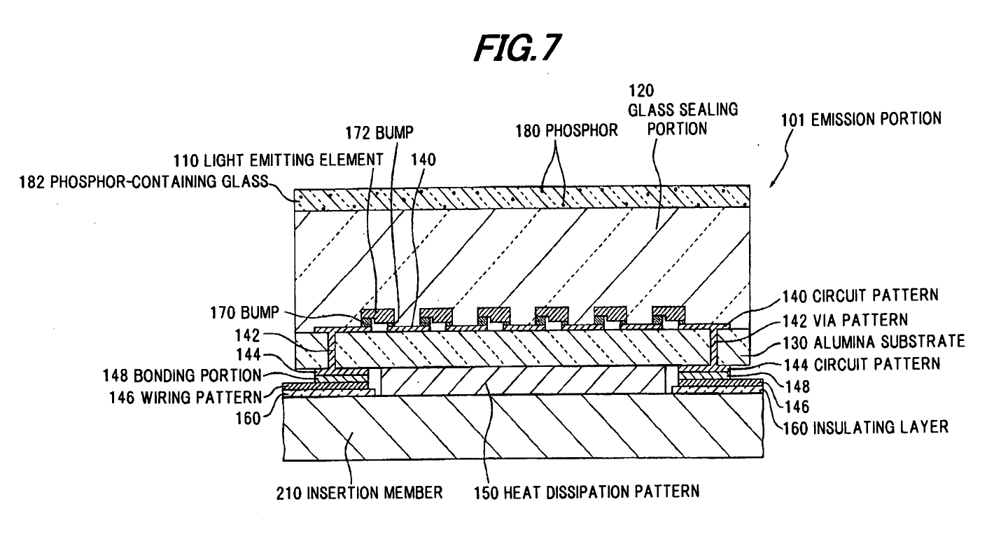

FIG. 7 is a cross sectional view showing a modification of the emission portion of the first embodiment.

The emission portion 101 in FIG. 7 is different from the emission portion 100 in FIG. 3A in that the glass sealing portion 120 does not include the phosphor 180 and instead a phosphor-containing glass 182 is formed on the glass sealing portion 120. The other parts are not different from each other and therefore not explained below.

The glass sealing portion 120 is first formed by sealing the plural light emitting elements 110 with the low-melting glass not containing the phosphor 180. Then, the phosphor-containing glass 182 containing the phosphor 180 therein is formed on the top surface of the glass sealing portion 120. For example, the phosphor-containing glass 182 is shaped like a rectangle (top view).

The phosphor-containing glass 182 is formed mainly of transparent and colorless low-melting point glass that can be hot-pressed at about 600° C., and has a thermal expansion coefficient of about 7×10⁻⁶/° C.). For example, the phosphor-containing glass 182 is formed of ZnO—SiO₂—R₂O-based glass material (where R is at least one element selected from alkali metal elements). The phosphor 180 included in the phosphor-containing glass 182 may be a yellow phosphor that radiates yellow light with a peak wavelength in a yellow region by being excited by blue light emitted from the light emitting element 110. For example, the phosphor 180 may be formed of a YAG phosphor.

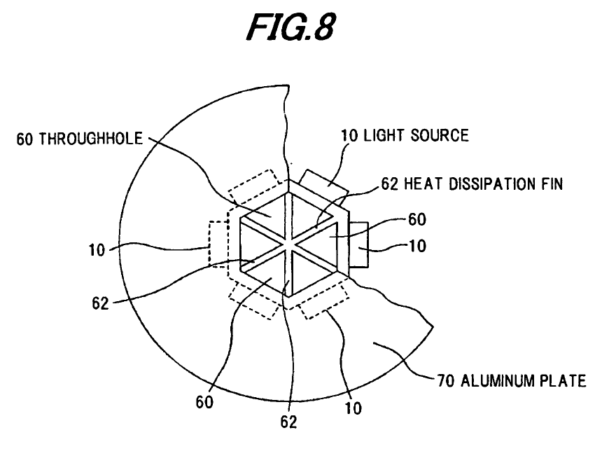

FIG. 8 is a bottom view showing a modification of the refection portion of the first embodiment.

The reflection portion 20 in FIG. 8 is different from the reflection portion 20 in the above embodiment in that heat dissipation fins 62 are attached inside the throughhole 60. The other parts are not different from each other and therefore not explained below.

The reflection portion 20 has the heat dissipation fin 62 attached inside the throughhole 60. For example, there are provided the six heat dissipation fins 62 as shown in FIG. 8. By the heat dissipation fins 62, the total surface area contacting the air of the surface of the throughhole 60 and the heat dissipation fins 62 can be increased as compared to the case that there is not provided the heat dissipation fins 62. The heat dissipation fins 62 may include a concave-convex or corrugated surface thereon.

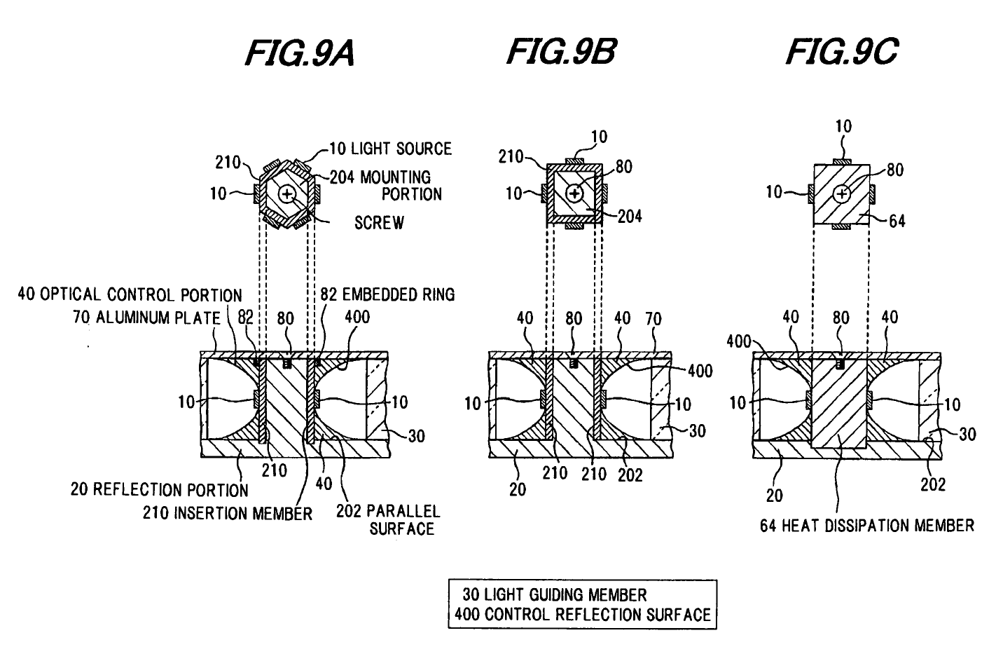

FIGS. 9A to 9C are cross sectional views showing a modification of the refection portion of the first embodiment.

As shown in FIGS. 9A to 9C, the modified reflection portion 20 is formed such that the throughhole 60 is eliminated or filled by a different material. The other parts are not different from each other and therefore not explained below.

As shown in FIG. 9A, the throughhole 60 as described above is replaced by the same material as the reflection portion 20. In other words, the mounting portion 204 of the reflection portion 20 extends inside of the insertion member 210 such that it is shaped like a hexagonal (top view) column and the plural light sources 10 are mounted via the insertion member 210 on the outside faces of the hexagonal column mounting portion 204. In this modification, the insertion member 210 has a throughhole for being fitted to the hexagonal column mounting portion 204. The plural light sources 10 are mounted on the outside faces of the insertion member 210, and the optical control portion 40 is formed surrounding the light sources 10. The insertion member 210 with the light sources 10 mounted thereon is fitted to the hexagonal column mounting portion 204.

In this modification, a predetermined space is previously formed between the optical control portion 40 and the insertion member 210. The light emitting device 1 of this modification is assembled such that the insertion member 210 with the light sources 10 mounted thereon is fitted to the mounting portion 204, an embedded ring 82 is inserted in the space, the aluminum plate 70 is placed thereon, and the aluminum plate 70 is fixed to the reflection portion 20 by the screw 80. Thus, heat generated from the light source 10 is transferred through the insertion member 210 to the reflection portion 20 and the mounting portion 204 of the reflection portion 20, such that it can be externally dissipated from the surface of the reflection portion 20 and the aluminum plate 70. The embedded ring 82 may be an O-ring of an elastic member such as ethylene propylene rubber, nitrile rubber, silicone rubber or fluorine-contained rubber.

Alternatively, as shown in FIG. 9B, the mounting portion 204 may be shaped like a square (top view) column. The parts other than the shape of the mounting portion 204 are the same as the modification in FIG. 9A and therefore not explained here.

As shown in FIG. 9C, the reflection portion 20 is provided with a heat dissipation member 64 as a mounting portion for mounting the light sources 10 thereon while eliminating the insertion member 210. The heat dissipation member 64 is shaped like a square (top view) column and has a thermal conductivity equal to or higher than the reflection portion 20. The light sources 10 are mounted on the outside faces of the heat dissipation member 64. The heat dissipation member 64 may be formed of the same material as the reflection portion 20.

The heat dissipation member 64 may be shaped like a triangle or polygonal (top view) column other than the square column. The heat dissipation member 64 may have a thermal conductivity higher than the reflection portion 20. In this case, the heat dissipation member 64 has desirably a thermal expansion coefficient smaller than the reflection portion 20.

### Effects of the First Embodiment

The light emitting device 1 of the first embodiment has the effect that light emitted from the light source 10 can be outputted from the light output surface 315 at ideal efficiency by the total reflection on the refection region 305 of the light guiding member 30. Also, light inputted to the refection region 305 at an angle smaller than the critical angle of the total reflection can be outputted through the parallel region 310 and the light output surface 315 after passing though the refection region 305 and being reflected on the reflection surface 200 of the reflection portion 20. Therefore, in viewing the light emitting device 1 from the top, the entire light output surface 315 of the light emitting device 1 can provide for uniform emission of light without generating a stripe emission pattern of light.

The light emitting device 1 of the first embodiment has the hollow portion 50 between the reflection surface 200 of the reflection portion 20 and the light guiding member 30. Thereby, heat generated from the light source 10 can be prevented from transferring to the refection region 305 and the parallel region 310 of the light guiding member 30 so as to prevent the deterioration of the refection region 305 and the parallel region 310 by the heating. Therefore, even when the light source 10 generates much heat, decrease in light output of the light emitting device 1 can be prevented that may be caused by the deterioration of the light guiding member 30 during the long-period operation thereof.

The light emitting device 1 of the first embodiment has the space filled with the air between the light source 10 and the light input surface 300 of the light guiding member 30. Thereby, the refractive angle 702 is made smaller than the incident angle 700 of light inputted to the interface between the space and the light input surface 300. As a result, light inputted at the incident angle 700 to the light input surface 300 from the light source 10 and the control reflection surface 400 can be collected within the small spread angle 710 in the light guiding member 30 (See FIG. 5B). In other words, light inputted obliquely to the light input surface 300 from the light source 10 and the control reflection surface 400 is refracted toward the propagation direction of light inputted perpendicularly to the light input surface 300. Thus, in this embodiment, the amount of light reaching the refection region 305 increases with respect to that of light inputted to the light input surface 300 as compared to the case without the space. Therefore, the rate of light reflected by the refection region 305 to light inputted to the light input surface 300 can be increased.

Further, due to the space, the refractive angle 702 can be smaller than the incident angle 700 as described above. Thus, light inputted from the light source 10 and the control reflection surface 400 to the light input surface 300 can be properly collected such that it can be outputted to the light output surface 315.

The light emitting device 1 of this embodiment is has the space filled with the air between the light source 10 and the light input surface 300 of the light guiding member 30 and the space is not filled with a transparent resin or the like. Due to the refractive index difference between the air and the glass sealing portion 120, of light directly inputted from the light emitting element 110 to the interface between the space and the glass sealing portion 120, light inputted at an angle beyond the critical angle to the interface is subjected to the internal total reflection at the interface. However, in this embodiment, since the phosphor 180 is dispersed in the glass sealing portion 120, there occurs no light confinement mode to have such an angle repeatedly causing the internal total reflection. Thereby, the amount of light equivalent to that as in the space filled with the transparent resin can be inputted from the light source 10 to the light guiding member 30. Thus, even when having the space filled with the air between the light source 10 and the light input surface 300, lowering in the amount of light inputted from the light source 10 to the light guiding member 30 can be prevented. In addition, due to the space between the light source 10 and the light input surface 300, the light emitting device 1 can be reduced in weight and material cost as well as being simplified in the manufacturing process.

The light emitting device 1 of this embodiment is has the light source 10 (emission portion 100) with dimensions different among width, length and thickness thereof. Therefore, the distance between the plural light emitting elements 110 of the light source 10 (emission portion 100) and the interface of the glass sealing portion 120 and the outside is different among the width, length and thickness directions. Thus, the chromaticity of light radially outputted from the light source 10 is different among the width, length and thickness directions. However, in this embodiment, light radially outputted from the light source 10 is reflected to be perpendicular to the light input surface 300 by the control reflection surface 400, and then reflected toward the light output surface 315 by the plural refection regions 305 provided at the predetermined intervals with the light guiding member 30. Therefore, in this embodiment, due to the optical system such as the optical control portion 40 and the light guiding member 30, light outputted from the light source 10 and different in chromaticity can be collected at the light output surface 315 such that unevenness in chromaticity of light externally outputted from the light output surface 315 can be reduced.

The light emitting device 1 of this embodiment is constructed such that the plural light emitting elements 110 are flip-chip bonded on a predetermined substrate and are sealed with glass so as to have the high-brightness and heat-resistant light source 10. Since the plural light emitting elements 110 are flip-chip bonded (without bonding wires), the number of the mountable light emitting elements 110 per unit area can be increased as compared to the case that the plural light emitting elements 110 are face-up bonded (with bonding wires) on a predetermined substrate.

Further, the alumina substrate 130 as the predetermined substrate has the same thermal expansion coefficient as glass composing the glass sealing portion 120. Even when much heat is generated by supplying large current to the light emitting elements 110 while small-packaging the light source 10, the glass sealing portion 120 can be prevented from separating from the alumina substrate 130 due to the difference in thermal expansion coefficient therebetween. Also, the glass sealing portion 120 can be prevented from deterioration caused by heat and light discharged from the light emitting elements 110 since it is formed of glass.

The light emitting device 1 of this embodiment is constructed such that the light source 10 is placed away from the light guiding member 30. In other words, the light source 10 is not in contact with the light guiding member 30. Therefore, even when much heat is generated by supplying large current to the plural light sources 10 while mounting the light sources 10 on the insertion member 210, heat generated is not directly transferred to the light guiding member 30 composed mainly of the transparent resin to deteriorate the light guiding member 30. Thus, even when continuing the operation of the light sources 10, the light emitting device 1 can be prevented from failures caused by the deterioration of the light guiding member 30.

The light emitting device 1 of this embodiment is constructed such that the light source 10 is shaped like a rectangle (top view) and has a longitudinal side (long side) and a width direction side (short side). Since the plural light emitting elements 110 of the light source 10 are in linear arrangement, the length of the light source 10 in width direction thereof can be smaller than the case that the plural light emitting elements 110 are in matrix arrangement. Thus, even when the light guiding member 30 is reduced in thickness, it is possible to suppress lowering in optical coupling efficiency between light emitted from the light source 10 and the light input surface 300.

The light emitting device 1 of this embodiment is constructed such that the light source 10 is mounted on the mounting portion 204 via the insertion member 210 formed of the material with a thermal expansion coefficient lower than that of the material composing the mounting portion 204 of the reflection portion 20. Therefore, thermal expansion/contraction lowers when the light source 10 is mounted on the insertion member 210 as compared to the case that the light source 10 is directly mounted on the reflection portion 20. Thus, even when repeating the operation of the light source 10 by supplying power thereto, the circuit pattern 144 of the emission portion 100 can be prevented from disconnecting from the wiring pattern 146 of the insertion member 210 for supplying power to the light source 10 due to the thermal expansion/contraction.

The light emitting device 1 of this embodiment is constructed such that the reflection portion 20 has the throughhole 60 so as to dissipate heat generated from the light sources 10 through the throughhole 60. Thus, even when there are provided the plural light sources 10 with the plural emission portions 100 including the plural light emitting elements 110, it is possible to suppress lowering in the emission efficiency of the light emitting device 1 due to heat from the light sources 10.

The light emitting device 1 of this embodiment is constructed such that the aluminum plate 70 as the cover member connected to the reflection portion 20 is provided while covering the light output surface 315 of the light guiding member 30 from outside of the light guiding member 30 and having the opening 92 for extracting light through the light output surface 315, and light emitted from the light source 10 can be reflected or refracted by the optical control portion 40 in direction of the light guiding member 30. Thus, heat generated from the light source 10 can be dissipated through both the light output surface side of the light emitting device 1 and the reflection portion 20 on the side opposite the light output surface side.

### Second Embodiment

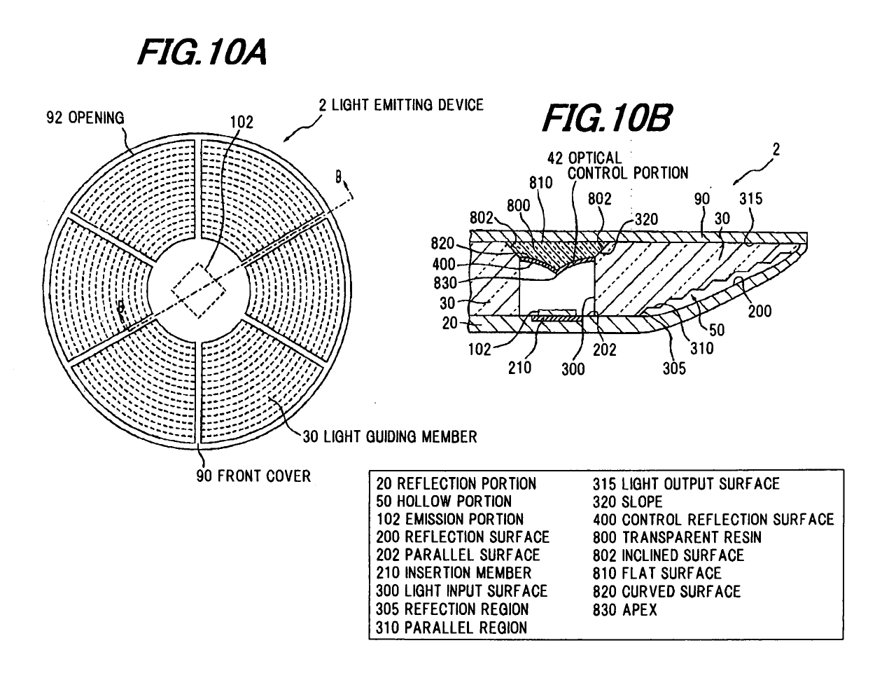

FIG. 10A is a bottom view showing a light emitting device in the second preferred embodiment according to the invention. FIG. 10B is a partial cross sectional view cut along a line B-B in FIG. 10A.

The light emitting device 2 of the second embodiment is different from the light emitting device 1 of the first embodiment in that there is newly provided an emission portion 102, the emission portion 102 is in specific arrangement, the reflection portion 20 has no throughhole, and there is newly provided an optical control portion 42. The other parts are not different from each other and therefore not explained below. The contacting part between the emission portion 102 and the insertion member 210 is described later.

Construction of the Light Emitting Device 2

The light emitting device 2 of this embodiment is composed of the emission portion 102 including plural light emitting elements, a reflection portion 20 on which the emission portion 102 is mounted via the insertion member 210 and which has the parallel surface 202 and the reflection surface 200, the optical control portion 42 which has a control reflection surface 400 for reflecting or refracting light emitted from the emission portion 102 in predetermined direction, and a transparent resin 800.

The light emitting device 2 is further constructed of the light guiding member 30 including the light input surface 300 to which light reflected or refracted by the control reflection surface 400 is inputted, the refection region 305 formed at a predetermined angle to light inputted through the light input surface 300, and the parallel region 310 formed nearly parallel to light inputted through the light input surface 300, the hollow portion 50 formed between the light guiding member 30 and the reflection portion 20, and a front cover 90 for covering the transparent resin 800 and the light guiding member 30 on the side of the light output surface 315.

The emission portion 102 is mounted via the insertion member 210 on the parallel surface 202 of the reflection portion 20. In other words, the emission portion 102 is disposed nearly parallel to the emission surface through which light emitting device 2 outputs light. The emission portion 102 is shaped like a square (top view). The light output surface 105 of the emission portion 102 is shaped like a square (top view). The emission portion 102 emits light in direction of the emission surface through which light emitting device 2 outputs light. In this embodiment, the emission portion 102 emits white light.

The transparent resin 800 is composed of a flat surface 810, an inclined surface 802 being inclined from the outer ends of the flat surface 810 and extending by a predetermined length, and curved surfaces 820 formed from the end of the inclined surface 802 and crossed at an apex 830. The transparent resin 800 is shaped like a circle (top view). The transparent resin 800 is formed in rotation symmetry with respect to an axis passing through the apex and center of the flat surface 810. For example, the transparent resin 800 is formed of a transparent acrylic resin. An angle defined between the flat surface 810 and the inclined surface 802 is an acute angle.

The light guiding member 30 of this embodiment is previously formed a slope 320 fitted to the inclined surface 802 of the transparent resin 800. The transparent resin 800 is fitted to the slope 320 previously formed on the light guiding member 30 such that the flat surface 810 is located on the side of the emission surface through which light emitting device 2 outputs light. Here, the flat surface 810 of the transparent resin 800 is arranged to be even with the light output surface 315. Meanwhile, the emission portion 102 is placed such that an intersection point of diagonal lines in the square (top view) emission portion 102 is nearly coincident with a point where a line formed connecting the apex 830 of the transparent resin 800 to the center of the flat surface 810 intersects with the surface of the emission portion 102.

The optical control portion 42 of this embodiment is formed on the curved surface 820 of the transparent resin 800. For example, the optical control portion 42 is formed of aluminum film on the surface of the curved surface 820. A surface of the optical control portion 42 opposite the curved surface 820 is the control reflection surface 400.

The front cover 90 is shaped like a circle (top view). For example, the front cover 90 is formed of aluminum alloy. The front cover 90 has plural openings 92 through which light discharged from a predetermined region of the light output surface 315 is outputted externally from the light emitting device 2. By the front cover 90, the transparent resin 800 and the light guiding member 30 are externally fixed to the reflection portion 20.

The material composing the optical control portion 42 may be freely selected according to wavelength of light emitted from the emission portion 102. For example, when the emission portion 102 emits blue, green or red light as monochromatic light, the optical control portion 42 may be formed of a material exhibiting a predetermined reflectively to wavelength of the light. The front cover 90 may be formed of a magnesium alloy or oxygen-free copper.

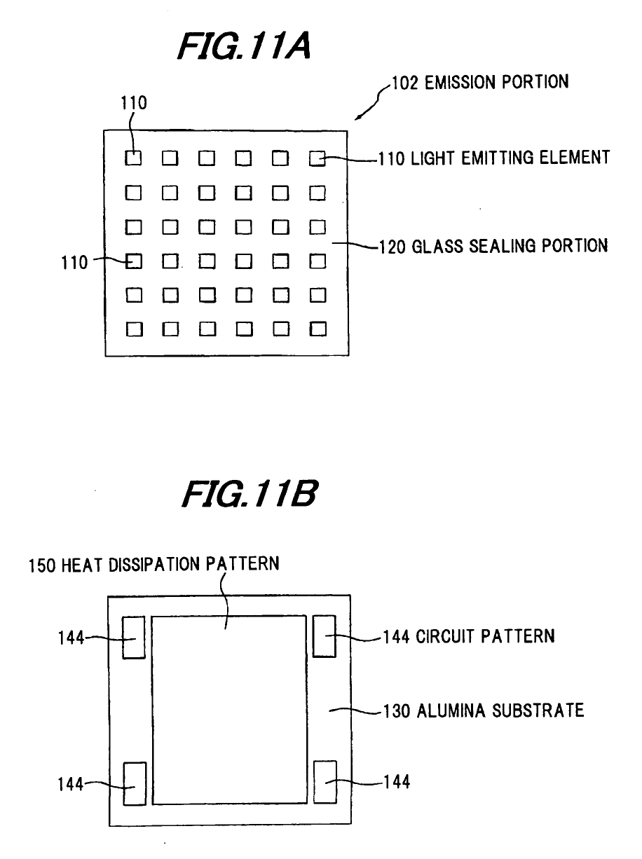

FIG. 11A is a top view showing the emission portion of the second embodiment. FIG. 11B is a bottom view showing the emission portion of the second embodiment.

The emission portion 102 of the second embodiment is different from the emission portion 100 of the first embodiment in that the plural light emitting elements 110 are different in arrangement. The other parts are not different from each other and therefore not explained below.

As shown in FIG. 11A, the emission portion 102 includes the plural light emitting elements 110. The plural light emitting elements 110 of the emission portion 102 is sealed with the glass sealing portion 120. The light emitting elements 110 sealed by the glass sealing portion 120 are arranged at intervals in the length and width directions. In other words, the light emitting elements 110 are in matrix arrangement.

In this embodiment, the emission portion 102 includes 6×6 light emitting elements 110. The number of the light emitting elements 110 included in the emission portion 102 is not limited to this. For example, the emission portion 102 may include n×n (where n=positive integer) light emitting elements 110 in matrix arrangement. The emission portion 102 may include only one light emitting element 110.

As shown in FIG. 11B, the circuit pattern 144 and the square heat dissipation pattern 150 are formed on the back of the emission portion 102, i.e., on the surface opposite the surface where the light emitting elements 110 are mounted of the alumina substrate 130. The heat dissipation pattern 150 can transfer to the insertion member 210 heat generated from the light emitting elements 110.

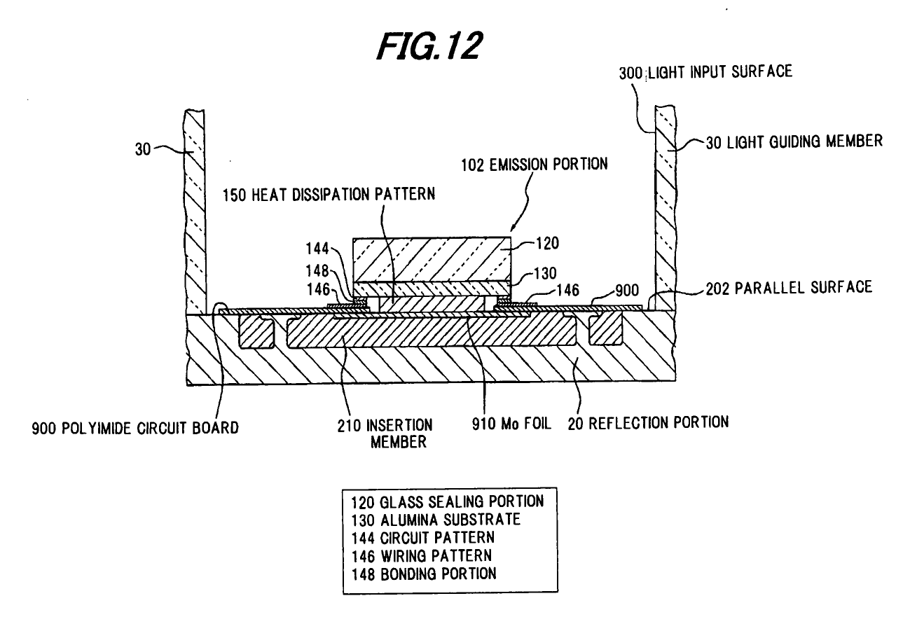

FIG. 12 is a cross sectional view showing the emission portion, the insertion member and the reflection portion of the second embodiment.

The emission portion 102 of the second embodiment is further different from the emission portion 100 of the first embodiment in that there is provided a Mo foil 910 between the heat dissipation pattern 150 and the insertion member 210 and there is provided a polyimide circuit board 900 with the wiring pattern 146 formed thereon. The other parts are not different from each other and therefore not explained below.

The insertion member 210 of this embodiment is included inside the reflection portion 20. On the insertion member 210, there are formed the Mo foil 910 in predetermined region, the polyimide circuit board 900 that contacts directly a part of the insertion member 210 and directly a part of the Mo foil 910, and the wiring pattern 146 that is previously formed on the polyimide circuit board 900. The emission portion 102 is bonded through the bonding portion 148 for electrically connecting the wiring pattern 146 and the circuit pattern 144 of the emission portion 102, to the polyimide circuit board 900.

The heat dissipation pattern 150 formed on the alumina substrate 130 of the emission portion 102 contacts the Mo foil 910. Thus, the Mo foil 910 formed on the insertion member 210 is shaped like a square (top view) and wider (top view) than the heat dissipation pattern 150. Heat generated from the emission portion 102 is transferred to the heat dissipation pattern 150, and through the Mo foil 910 to the insertion member 210. Molybdenum (Mo) composing the Mo foil 910 is 140 W/mK in thermal conductivity and 4 to 5×10⁻⁶/° C.

Operation of the Light Emitting Device 2

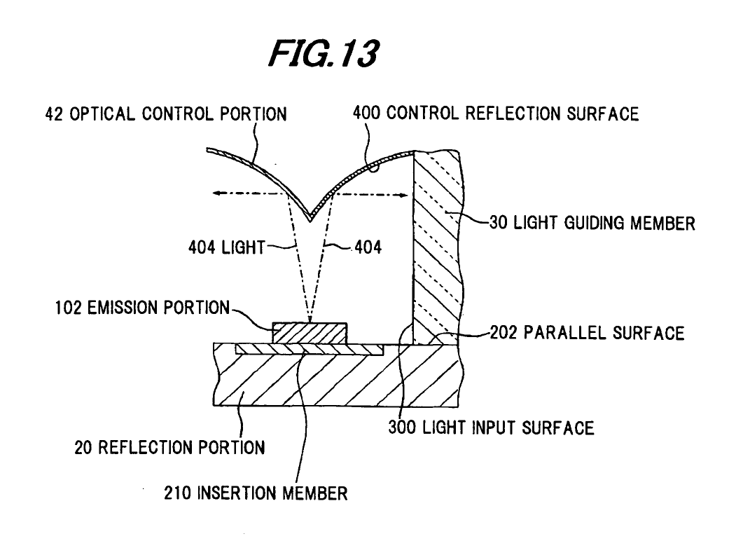

FIG. 13 is a bottom view showing a part of the light emitting device of the second embodiment.

The light emitting device 2 of the second embodiment is further different from the light emitting device 1 of the first embodiment in behavior of light emitted from the emission portion 102 until being inputted to the light input surface 300. The other points or functions are not different from each other and therefore not explained below.

Light emitted from the emission portion 102 is reflected or refracted by the control reflection surface 400 of the optical control portion 42 in direction of the light input surface 300. Thus, light 404 thus reflected or refracted in direction of the light input surface 300 is inputted to the light input surface 300. Behaviors after being inputted to the light input surface 300 are the same as the light emitting device 1.

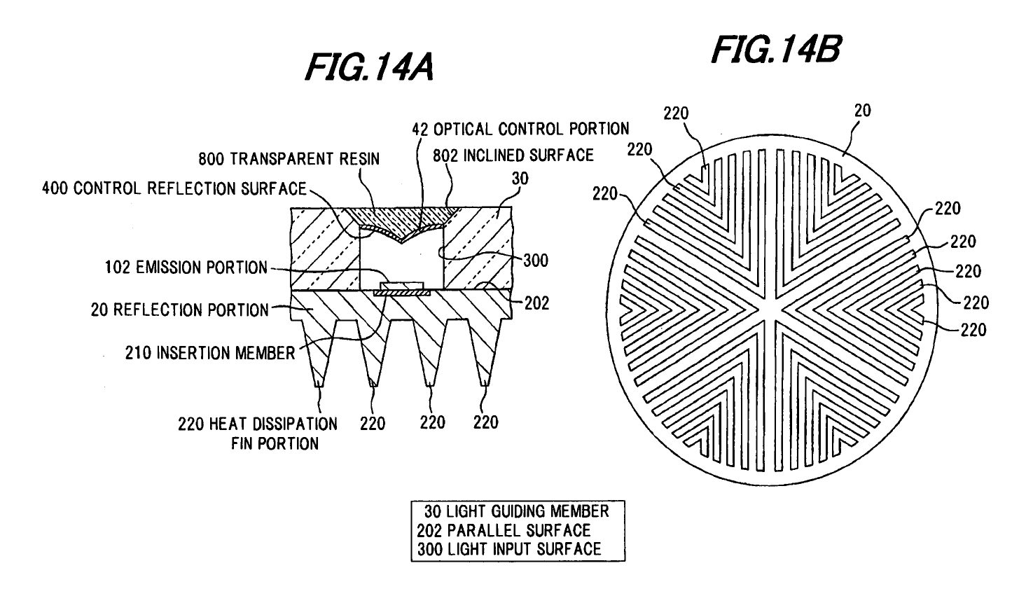

FIG. 14A is a cross sectional view showing a part of a modification of the light emitting device of the second embodiment. FIG. 14B is a bottom view showing the modification of the light emitting device of the second embodiment.

As shown in FIG. 14A, the reflection portion 20 of this modification is provided with plural heat dissipation fin portions 220 on its surface opposite the surface where the emission portion 102 is mounted. As shown in FIG. 14B, the plural heat dissipation fin portions 220 are formed in predetermined shape on the surface opposite the surface where the emission portion 102 is mounted of the reflection portion 20. Thus, surface area for dissipating heat generated from the emission portion 102 can be increased as compared to the case without protrusions such as the heat dissipation fin portions 220 on the surface opposite the surface where the emission portion 102 is mounted of the reflection portion 20.

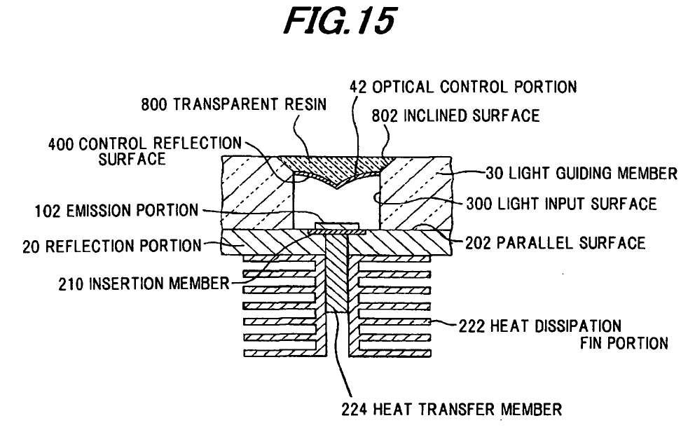

FIG. 15 is a cross sectional view showing a part of another modification of the light emitting device of the second embodiment.

The reflection portion 20 of this modification is provided with a hole below the emission portion 102 and the insertion member 210. The light emitting device 2 of this modification is composed of a heat transfer member 224 inserted through the hole and contacting the insertion member 210, and a heat dissipation fin portion 222 contacting the reflection portion 20 and surrounding contiguously the heat transfer member 224.

For example, the heat transfer member 224 is shaped like a cylindrical column. The heat transfer member 224 is formed of a material with thermal conductivity higher than that of the material composing the reflection portion 20. For example, the heat transfer member 224 is formed of oxygen-free copper. For example, the heat dissipation fin portion 222 is formed of aluminum alloy. Alternatively, it may be formed of magnesium alloy or oxygen-free copper. Further, the heat dissipation fin portion 222 may include a concave-convex or corrugated surface thereon.

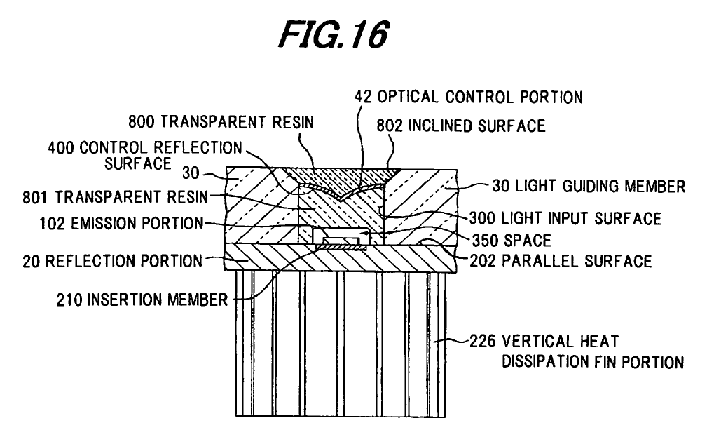

FIG. 16 is a cross sectional view showing a part of a further modification of the light emitting device of the second embodiment.

The reflection portion 20 of this modification is provided with a space or gap 350 on the upper and side periphery of the emission portion 102. A transparent resin 801 is formed such that it surrounds the emission portion 102 via the space or gap 350 and it contacts the control reflection surface 400 of the optical control portion 42 as well as the light input surface 300 of the light guiding member 30. The space or gap 350 is mainly occupied by the air. Thus, heat generated from the emission portion 102 is mainly transferred through the insertion member 210 to the reflection portion 20 without being transferred to the transparent resin 801 so much.

The transparent resin 801 is formed of the same material as the transparent resin 800. A vertical heat dissipation fin portion 226 attached under the reflection portion 20 has the same function and effect as the heat dissipation fin portion 222 in FIG. 15.

### Effects of the Second Embodiment

The light emitting device 2 of the second embodiment has the effect that the optical control portion 42 allows light generated from the emission portion 102 to be almost inputted to the light guiding member 30. Thus, the light emitting device 2 can externally discharge light emitted from the emission portion 102 at high efficiency.

The light emitting device 2 of the second embodiment has the effect that heat generated from the emission portion 102 can be dissipated through the insertion member 210 and the reflection portion 20. Thus, even when much heat is generated from the emission portion 102 with the plural light emitting elements 110, the heat can be dissipated through the reflection portion 20 so as to prevent lowering in emission efficiency of the light emitting device 2.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A light emitting device, comprising:
an emission portion;
an optical control portion for reflecting or refracting light emitted from the emission portion in a predetermined direction;
a light guiding member comprising a light input surface to which the reflected or refracted light is inputted, a refection region formed on a surface thereof for reflecting the inputted light, and a light output surface for externally outputting the reflected light from the refection region;
a reflection portion, on which the emission portion is mounted and which covers externally the refection region, for dissipating heat generated from the emission portion and for reflecting light passing through the refection region in a direction of the light output surface; and
a space formed between the light guiding member and the reflection portion.

2. The light emitting device according to claim 1, wherein:
the emission portion comprises a flip-chip mounted light emitting element.

3. The light emitting device according to claim 2, wherein:
the emission portion further comprises a glass material for sealing the light emitting element.

4. The light emitting device according to claim 3, wherein:
the light guiding member further comprises a parallel region formed on a surface thereof, adjacent to the refection region and parallel to the inputted light to the light input surface; and
the parallel region which allows light reflected by the reflection portion to pass therethrough.

5. The light emitting device according to claim 4, wherein:
the light guiding member further comprises a plurality of the refection regions and a plurality of the parallel regions; and
the plurality of the refection regions and the plurality of the parallel regions are arranged alternately and serially.

6. The light emitting device according to claim 5, wherein:
the emission portion comprises a plurality of the light emitting elements disposed at predetermined intervals.

7. The light emitting device according to claim 6, wherein:
the plurality of the light emitting elements are disposed linearly.

8. The light emitting device according to claim 6, wherein:
the plurality of the light emitting elements are disposed in a matrix arrangement.

9. The light emitting device according to claim 3, wherein:
the glass material includes a phosphor for wavelength-converting light emitted from the light emitting element.

10. The light emitting device according to claim 1, further comprising:
an insertion member between the emission portion and the reflection portion, the insertion member comprising a thermal expansion coefficient smaller than that of the reflection portion.

11. The light emitting device according to claim 1, wherein:
the reflection portion comprises an annular mounting portion on which a plurality of the emission portions are mounted, and a throughhole inside the annular mounting portion.

12. The light emitting device according to claim 11, wherein:
the reflection portion further comprises a heat dissipation fin inside the throughhole.

13. The light emitting device according to claim 1, wherein:
the reflection portion comprises a mounting portion on which a plurality of the emission portions are mounted, and which comprises a thermal conductivity equal to or higher than the reflection portion.

14. The light emitting device according to claim 1, further comprising:
a cover member that covers externally the light output surface of the light guiding member, comprises an opening for extracting therethrough light outputted from the light output surface, and is connected to the reflection portion.
